(19) United States
(12) Patent Application Publication
(10) Pub. No.: US 2004/0042625 A1
(43) Pub. Date: Mar. 4, 2004

(54) Equalization and load correction system and method for audio system

(76) Inventor: C. Phillip Brown, Castro Valley, CA (US)

Correspondence Address: WILSON SONSINI GOODRICH & ROSATI, 650 PAGE MILL ROAD, PALO ALTO, CA, 943041050

(21) Appl. No.: 10/230,878

(22) Filed: Aug. 28, 2002

(51) Int. Cl. H03G 5/00

(52) U.S. Cl. 381/103

(57) ABSTRACT

Load correction systems and methods. In one embodiment, the load correction system includes an audio source signal and a parametric equalizer coupled to receive the source signal. A summation is configured to combine an inverse of the source signal with an output of the equalizer. An amplifier is configured to receive an output of the summation, and a speaker is coupled to receive an output of the amplifier. According to an embodiment, the equalizer comprises an adjustable equalizer. According to another embodiment, a digital signal processor implements the equalizer and summation. According to yet another embodiment, in absence of the filter, a combination of the speaker and electronic components coupled with the speaker have a larger amount of phase at low frequencies and a smaller amount of phase at high frequencies.

### BACKGROUND OF THE INVENTION

1. Field of the Invention

This invention relates to the field of signal processing and audio systems.

2. Background

Technology for improving the response of components in audio systems has seen improvement in recent years. For example, techniques are used to optimize the construction of audio speakers for improved sound quality. Some techniques involve using selected materials such as special kinds of wood, sizing the closure to match certain characteristics of the speakers or other optimizations. Materials may be added to speakers to provide improvement of sound quality. Consumers still desire higher quality sound systems. Further, with the proliferation of electronic devices, consumers continue to use items with lower quality speakers and equipment not benefitting from some of the known technology for optimal sound.

In addition to improvements to speakers, improved electronics are provided to increase the performance of audio systems. For example, numerous filters have been proposed to correct for magnitude response of audio systems, in particular in order to correct for deficiencies in speakers. Despite the advances in such technologies, there remains a need for improved audio circuits and systems to help produce improved sound quality in various environments.

### SUMMARY

An embodiment of the invention is directed to a load correction system. The load correction system includes an audio source signal and a parametric equalizer coupled to receive the source signal. A summation is configured to provide a difference between the source signal and an output of the equalizer. An amplifier is configured to receive an output of the summation, and a speaker is coupled to receive an output of the amplifier. The summation may add an inverse of the source signal to an output of the equalizer, or, alternatively, add the source signal to an inverse of an output of the equalizer. According to an embodiment, the equalizer comprises an adjustable equalizer. According to another embodiment, a digital signal processor implements the equalizer and summation. According to yet another embodiment, in absence of the filter, a combination of the speaker and electronic components coupled with the speaker have a larger amount of phase at low frequencies and a smaller amount of phase at high frequencies.

Another embodiment of the invention is directed to an audio system. The audio system includes an enclosure comprising a synthetic material. One or more speakers are coupled to an interior service of the enclosure. The system also includes electronic components and a display device. The electronic components and the display device are contained in the enclosure, and the electronic components include an amplifier coupled to at least one of the one or more speakers. The system also includes an integrated circuit. The integrated circuit has an input circuit configured to receive a source signal. The integrated circuit also has a filter with coefficients. The coefficients are derived from a parametric equalizer coupled to a summation of a difference between an input to the equalizer and an output of the equalizer. The integrated circuit also has an output circuit configured to receive and output an output of the filter. The output of the circuit is coupled to an input of the amplifier. The summation may combine an inverse of the source signal with an output of the equalizer, or, alternatively, combine the source signal with an inverse of an output of the equalizer.

Various configurations of the system are possible, according to various embodiments. For example, the synthetic material may comprise plastic. At least one of the one or more speakers and the display device are located in a single cavity in the enclosure, according to another embodiment. The display device may comprise a cathode ray tube, or a flat panel display, according to various embodiments. The speakers may have a single cone, and may be of the same size, according to various embodiments of the invention. The system may include a user interface that provides for disabling the filter and adjustment of treble and bass.

Another embodiment of the invention is directed to an audio system that includes one or more speakers, electronic components and an integrated circuit. The integrated circuit has an input circuit configured to receive a source signal, a filter and an output to the circuit to receive an output and output of the filter. The filter has coefficients derived from a parametric equalizer coupled to a summation of a difference between an input to the equalizer and an output of the equalizer. The output circuit is coupled to an input of the amplifier, and receives and outputs an output of the filter. The summation may combine an inverse of the source signal with an output of the equalizer, or, alternatively, combine the source signal with an inverse of an output of the equalizer.

According to various embodiments of the invention, the system may include a magnetic tape audio and video reading device, where the source signal is supplied by the reading device. In another embodiment, the system includes a portable headphone that comprises the speaker.

According to another embodiment to the invention, the system includes digital and versatile disks (DVD) reading logic. The DVD reading logic supplies the source signal. According to another embodiment, the system includes a processor, hard drive storage device, display device and telecommunications software.

In another embodiment of the invention, the speaker is housed in a cavity of an automobile. The cavity may comprise a cavity in a door of the automobile, or other cavity, such as a cavity on the rear of the automobile connecting with the trunk area.

Another embodiment of the invention is directed to a method of signal processing. A filter is derived from a parametric equalizer coupled to a summation of a difference between an inverse of an input to the equalizer and an output of the equalizer. A source signal is received, and the filter is applied to the source signal. An output of the filter is provided to an amplifier coupled to a speaker. The summation may combine an inverse of the source signal with an output of the equalizer, or, alternatively, combine the source signal with an inverse of an output of the equalizer.

Another embodiment of the invention is directed to a load correction circuit. The circuit includes an input circuit configured to receive a source signal. Also included is a filter with coefficients and a circuit to receive and output an output of the filter to an amplifier. The coefficients are derived from a parametric equalizer coupled to a summation of a difference between an input to the equalizer coupled and an output of the equalizer. The equalizer may comprise an adjustable parametric equalizer, according to an embodiment of the invention. Also included may be a digital signal processor and memory to store computer readable instructions implementing the filter. According to another embodiment, the coefficients are adjustable after at least some use of the circuit. The summation may combine an inverse of the source signal with an output of the equalizer, or, alternatively, combine the source signal with an inverse of an output of the equalizer.

### BRIEF DESCRIPTION OF THE DRAWINGS

FIG. 1 is a block diagram of an audio system, according to an embodiment of the invention.

FIG. 2 shows a series of frequency and phase response curves according to an embodiment of the invention.

FIG. 3 is an illustrative and block diagram of a system with a CRT, according to an embodiment of the invention.

FIG. 4 is a series of response curves in systems and/or components according to an embodiment of the invention.

FIG. 5 is a block diagram of a system with a digital signal processor, according to an embodiment of the invention.

FIG. 6 is a flow diagram of application of equalization, according an embodiment of the invention.

FIG. 7 is a block diagram illustrating production of media according to an embodiment of the invention.

FIG. 8 is an illustrative diagram of a vehicle with stereo system and equalizing filter, according to an embodiment of the invention.

FIG. 9 is a schematic drawing of an analog circuit, according to an embodiment of the invention.

FIG. 10 is a schematic diagram of an analog circuit with feed-forward, according to an embodiment of the invention.

FIG. 11 is a schematic diagram of an analog circuit, according to an embodiment of the invention.

### DETAILED DESCRIPTION

An embodiment of the invention is directed to an improved audio system. An input audio signal is received, and an improved signal is output to amplifier. The input signal is processed so as to have a larger amount of phase at lower frequencies than would otherwise be the case in the absence of an embodiment of the invention. The input signal is processed with a circuit that is derived from a parametric equalizer receiving the source signal, wherein inverse of the source signal is combined with an output of the equalizer. The summed output of the circuit is provided to the amplifier, and the output of the amplifier is provided to a speaker.

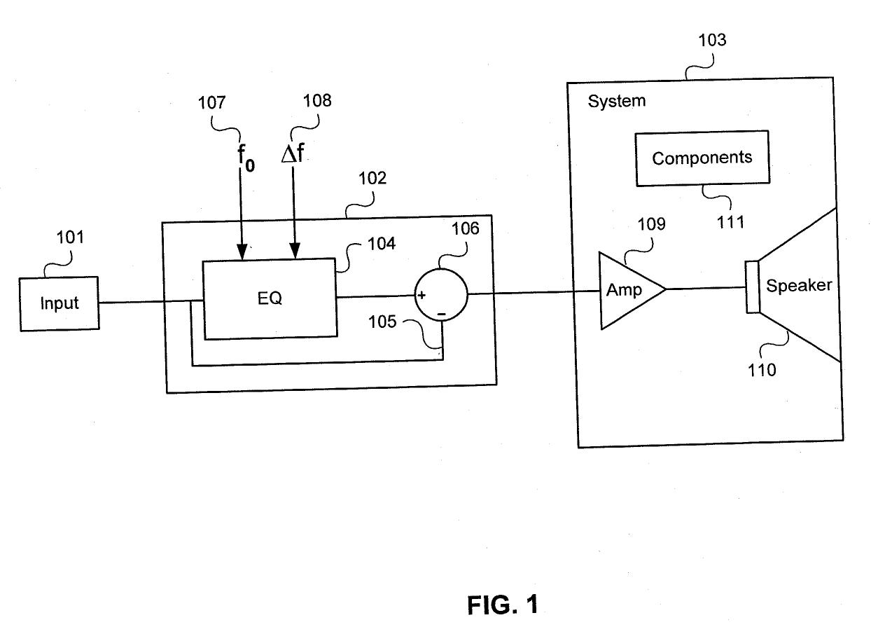

FIG. 1 is a block diagram of an audio system, according to an embodiment of the invention. Included are input 101, phase corrected circuit 102 and system 103. Circuit 102 includes equalizer 104, connection 105 and summation 106. Also included in phase corrected circuits 102 are inputs f₀ 107 and Δf 108. System 103 includes an amplifier 109 and speaker 110 as well as components 111.

Items shown in FIG. 1 are connected as follows. Input 101 is coupled with phase corrected circuit 102, and phase corrected 102 is coupled with system 103. Input 101 is received by equalizer circuit 104, which also receives inputs of f₀ 107 and Δf 108. The output of equalizer circuit 104 is provided to summation 106, which receives connection 105 from input 101. The output of summation 106 is provided to amplifier 109, the output of which is provided to speaker 110.

The system may operate as follows. An audio signal is provided by input 101 to phase corrected circuit 102. Equalizer circuit 104 is adjustable with respect to a null and bandwidth by inputs f₀ 107 and Δf 108 respectively. The output of equalizer 104 is provided to summation 106, which sums the output of equalizer 104 with the input to equalizer by way of connection 105. Alternatively, at summation 106, the output of equalizer 104 is subtracted from the input of equalizer 104. The signal, which has been processed by phase corrected circuit 102 is then provided to amplifier 109, which provides an amplified signal to speaker. Components 111 provide for other aspects of system 103. For example, components 111 may comprise electronics for video processing and output. Further, such components may allow for user input and control of system 103.

Phase corrected circuit 102 may be implemented in various ways. For example, the functionality shown may be implemented through a digital filter. A digital filter may implement the equalizer of equalizer 104, and inverse of the input may be added to the output of the equalizer. Alternatively, a single filter derived from the combination of the equalizer and summation may be implemented, according to an embodiment for the invention.

For example, a digital filter H(z) may be implemented in accordance with the following initial design:

$$H ( z ) = \frac{{b}_{0} + {b}_{1} {z}^{- 1} + {b}_{2} {z}^{- 2}}{1 + {a}_{1} {z}^{- 1} + {a}_{2} {z}^{- 2}} .$$

The filter H(z) may be applied to an input X(z), and the input X(z) may be subtracted from the filter as follows:

Y(z)=X(z)H(z)−X(z)

The phase corrected circuit may be implemented as Y(z)=X(z)H′(z), where H′(z)=H(z)−1. H′(z) can be implemented:

$${H}^{′} ( z ) = \frac{( {b}_{0} - 1 ) + ( {b}_{1} - {a}_{1} ) {z}^{- 1} + ( {b}_{2} - {a}_{2} ) {z}^{- 2}}{1 + {a}_{1} {z}^{- 1} + {a}_{2} {z}^{- 2}}$$

The coefficients shown above may be described as:

b₀′=b₀−1

b₁′=b₁−a₁

b₂′=b₂−a₂

Thus, the circuit with an equalizer having an inverse of its input added to the output may be implemented as a filter with modified coefficients. According to another implementation, the output of the filter is subtracted from the input. An equalizer is then implemented having the input added to an inverse of its output as a filter with modified coefficients.

The following is an example of computer-readable code illustrating design of an exemplary embodiment:

| | |
|---|---|
| Fs = 44100; | % sample rate (Hz) |
| db_peak = −16; | % height/depth of peak in db |
| db_bw = −12; | % height/depth at specified bandwidth in |
| | db |
| f0 = 700; | % center freq (freq of peak) in Hz |
| bw = 800; | % bandwidth in Hz |
| G0 = 3; | % reference gain |
| G = 10\hat{ }(db_peak/20) *G0; | % mm/max filter gain |
| GB = 10\hat{ }(db_bw/20) *G0; | % gain at bandwidth Dw |
| w0 = 2*pi*f0/fs; | % freq of peak in radians/sample |
| Dw = 2*pi*bw/fs; | % bandwidth in radians/sample |
| | % - H(z) is the resulting filter |

beta = tan(Dw/2) * sqrt (abs (GB\hat{ }2 − G0\hat{ }2) ) / sqrt (abs (G\hat{ }2 − GB\hat{ }2));
b = [G0 + G*beta), −2*G0*cos (w0), (G0 − G*beta)] / (1+beta);
a = [1, −2*cos (w0) / (1+beta), (1−beta) / (1+beta)];
% get freq response of parametric EQ
[h,f] = freqz (b,a,1024,fs);
%H(z) −1
b(1) = b(1) −1;
b(2) = b(2) − a(2);
b(3) = b(3) −a(3);

| | |
|---|---|
| b = b*1.75; | %gain: G* (H(z) −1) |

% get the frequency response of the phase corrected EQ
[h2,f] = freqz (b, a, 1024, fs);

Implementations in digital signal processors may be provided according to the following exemplary embodiments. Digital implementation can be accomplished on both fixed and floating point DSP hardware. It can also be implemented on RISC or CISC based hardware (such as a computer CPU).

According to one embodiment of the invention, bass or treble boost can be independently varied over a large range of values. Additionally, the width and shape of the filter slopes can be varied over a large range of values. Phase delay is, according to one embodiment, approximately +360° at the lowest frequency, steadily decreasing to 0° at the highest frequency. While the shape of the magnitude of the filter can very greatly (null frequency, bandwidth, gain), the phase is consistently 360 degrees at the lowest frequency, steadily decreasing to 0 degrees at the highest frequency according to at least one embodiment.

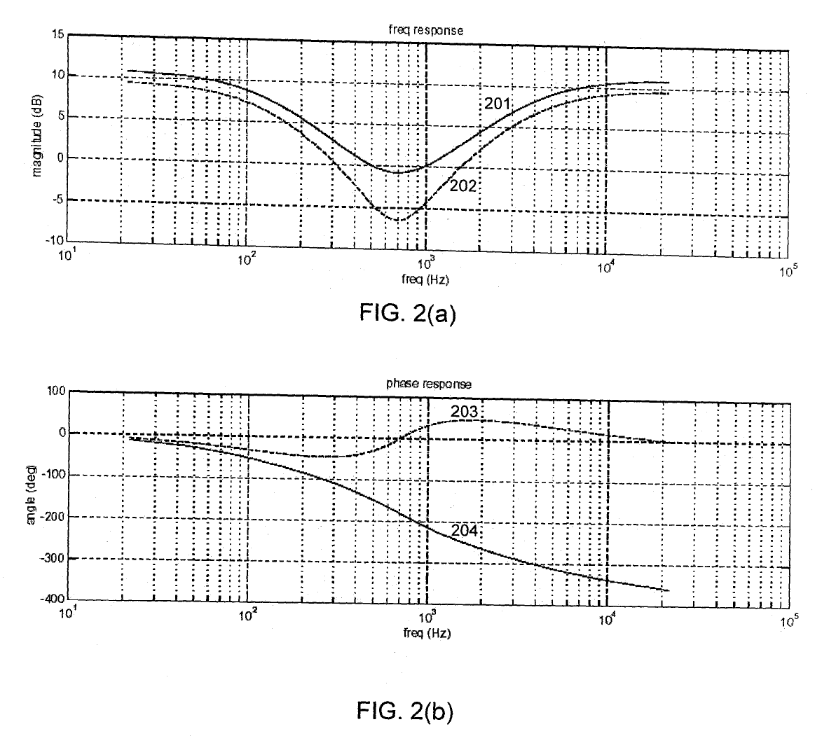

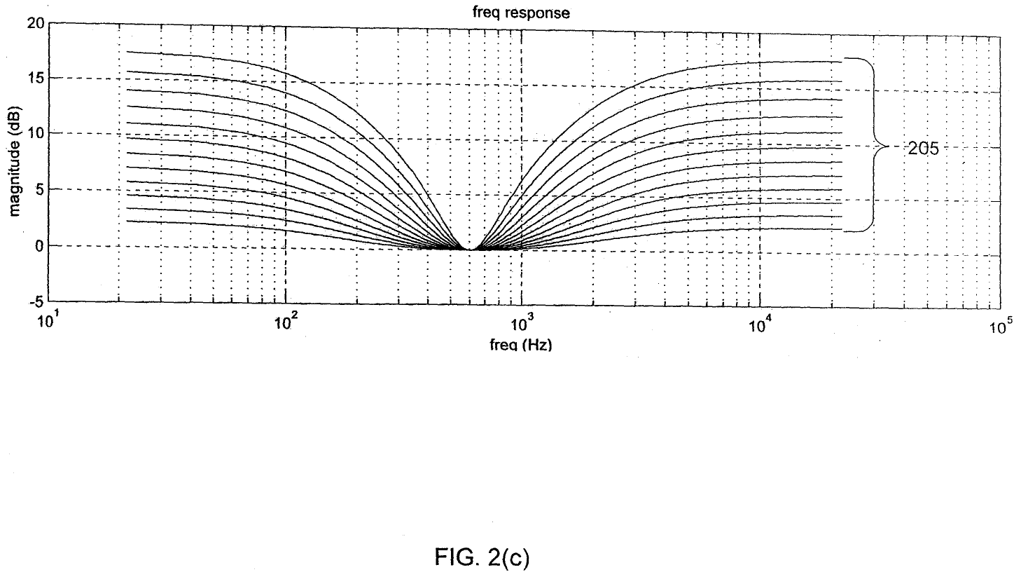

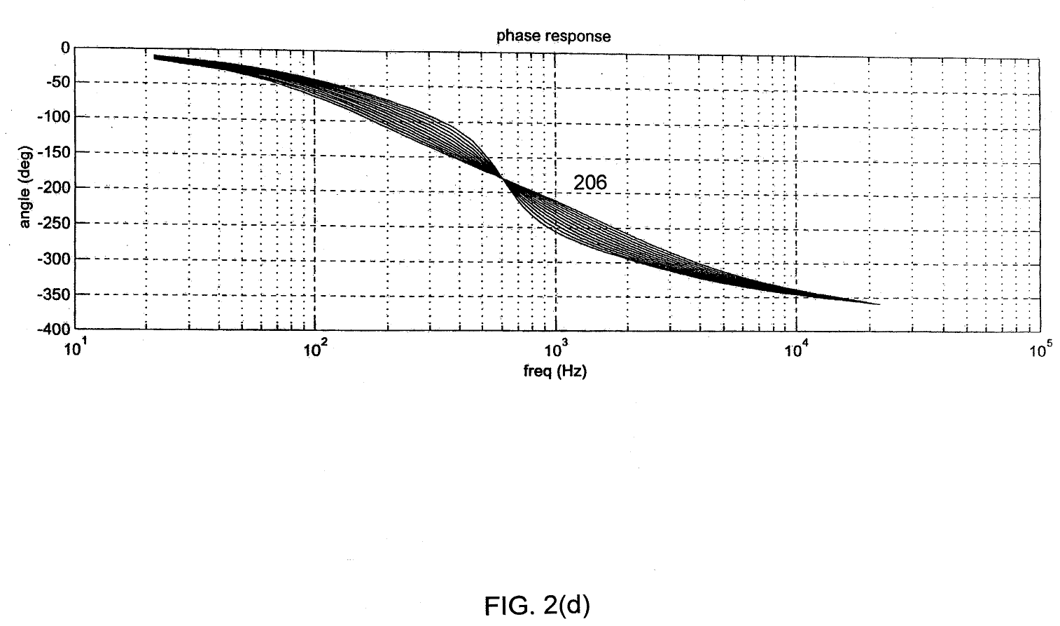

FIG. 2 is a series of frequency and phase response curves according to an embodiment of the invention. FIG. 2(a) shows a frequency response from the phase corrected circuit, according to one embodiment. Frequency responses are shown in magnitude in units of decibels. Frequency is shown on an exponential scale. Trace 202 shows frequency response in a system without the phase corrected circuit, and trace 201 shows frequency response of the phase corrected circuit, according to an embodiment.

FIG. 2(b) shows phase response, according to an embodiment. Phase response is shown in units of degrees. Frequency is shown on an exponential scale. Trace 203 shows phase response of a hypothetical system without a phase corrected circuit. Trace 204 shows phase response in a system with a phase corrected circuit, according to an embodiment. The phase response in trace 204 tends to be more linear than phase response 203. Phase response trace 204 also shows a greater amount of phase in the lower frequencies.

FIG. 2(c) shows a family of frequency response traces, according to an embodiment. Traces 205 are shown in magnitude decibels over different frequencies, which are shown on an exponential scale. Such traces represent different responses from a phase corrected circuit in which the filter has different sets of parameters for bandwidth.

FIG. 2(c) shows phase response in a series of traces, according to an embodiment of the invention. Phase response traces 206 correspond to the respective traces 205 in FIG. 2(c). Phase responses 206 tend to be more linear for those traces 205 which have a greater bandwidth].

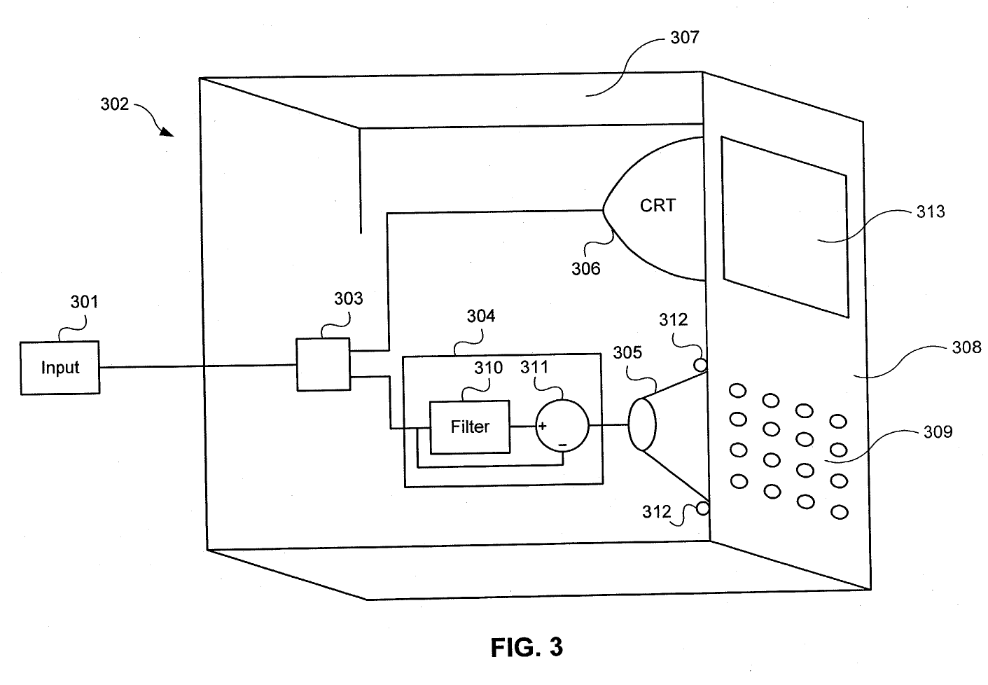

FIG. 3 is an illustrative and block diagram of a system with a CRT, according to an embodiment of the invention. The system includes an input 301 coupled into an audio video device 302. Audio video device 302 may comprise a device such as a television, or alternatively, a video monitor for a computer system or other device which outputs images and sound. Audio video device 302 includes plastic material 307, which includes front panel 308. Audio video system 302 also includes splitter circuit 303, cathode ray tube (CRT) 306, speaker 305 and phase corrected circuit 304. Phase corrected circuit 304 includes filter 310 and summation 311.

Audio video system 302 may be configured as follows. Splitter 303 is configured to receive input from input 301. The input of phase corrected circuit 304 and the input of cathode ray tube 306 are coupled to the output of splitter 303. The input of speaker 305 and coupled to the output of phase corrected circuit 304. System 302 is housed by an enclosure comprising plastic material 307, according to one embodiment. Speaker 305 is connected to a front panel 308 of system 302 by screws 312.

System 302, according to an embodiment, is not optimally constructed with housing for speaker 312. For example, rather than being glued and mounted flush with a front panel of a speaker housing, speaker 305 is connected to front panel 308 with the screws at grill 309. Note that speaker 305 may be accompanied by other speakers in system 302. However, such other speakers are of the same type as speaker 305 such that system 302 does not include a range of different speakers such as woofers and tweeters in combination in order to accommodate both high and low range frequencies. Additionally, according to an embodiment, speaker 305 is located in the same cavity of system 302 as other components, such as CRT 206 and electronics not directly needed for the operation of speaker 305. System 302 may also lack other features related to optimal speaker output such as mounting for the speaker with an optimally sized hole. The enclosure may not be sized relative to the speaker according to Theil and Small dimensions. Further, the speaker may be not sealed in the enclosure, and the enclosure may be leaky allowing air to pass into the enclosure in a non-optimal manner. Speaker 305 has a limited frequency response, according to an embodiment, and may be comprised of a single cone, such as in a woofer, without a tweeter. According to an embodiment, speaker 305 has a relatively large coil with high inductance. The inductance of the coil creates a larger impedance as frequency increases, resulting in a time delay (the higher frequencies have a larger phase shift, causing a greater time delay than at the lower frequencies). According to an embodiment, speaker 305 has a relatively large coil with high inductance, in one embodiment on the order of 0.1-10 milli Henries (mH). Additionally, due to the improper acoustic loading in many commercial applications (like television), the low frequency response of the speaker can be compromised. The low frequency cut-off will be higher than in an optimal configuration. Without a tweeter, the high frequencies will be “rolled off” and therefore not perceptible. Additionally, loudspeaker crossovers will add phase shift to the input signal, further corrupting the phase. Further, system 302 may lack diffusion material on internal walls. Rather, plastic material 307 is directly exposed, according to an embodiment. System 302 may also be constructed without a crossover circuit for speaker 305. According to other embodiments, versions of the circuits and systems may also be used in systems having more optimal speakers and configurations of speakers and speaker equipment, such as various combinations of the optimal constructions discussed above.

In operation, an input signal 302, which includes both video and audio signals, is provided to system 302. Such input 301 is separated into separate video and audio signals at splitter 303. The video and audio signals are provided to CRT 306 and phase corrected circuit 304 respectively. Additional electronics for processing the video and audio signals respectively may be included, according to various embodiments. For example, electronics for processing an MPEG signal may be included, according to an embodiment of the invention. Additionally, other electronics to provide adjustment of the respected signals and user control may be provided. For example, electronics for the configuration of volume, tuning, various aspects of sound, quality and reception may be provided. Additionally, in an embodiment in which system 302 comprises a television, a tuner can be provided. In such case, input 301 may represent an input received from a broadcast of radio waves. Input 301 may also represent a cable input, such as one received in a cable television network. According to another embodiment of the invention, CRT 306 is replaced with a flat panel display, or other form of video or visual display. System 302 may also comprise a monitor for a computer system, where input 301 comprises an input from the computer.

Phase corrected circuit 304 may be implemented in digital electronics, such as by a digital filter implemented by a digital signal processor. Such digital signal processor performs other functions in system 302, according to an embodiment. For example, such a digital signal processor may perform other filtering, tuning and other processing for system 302. Phase corrected circuit 304 may be implemented as a series of separate components or as a single integrated circuit, according to different embodiments.

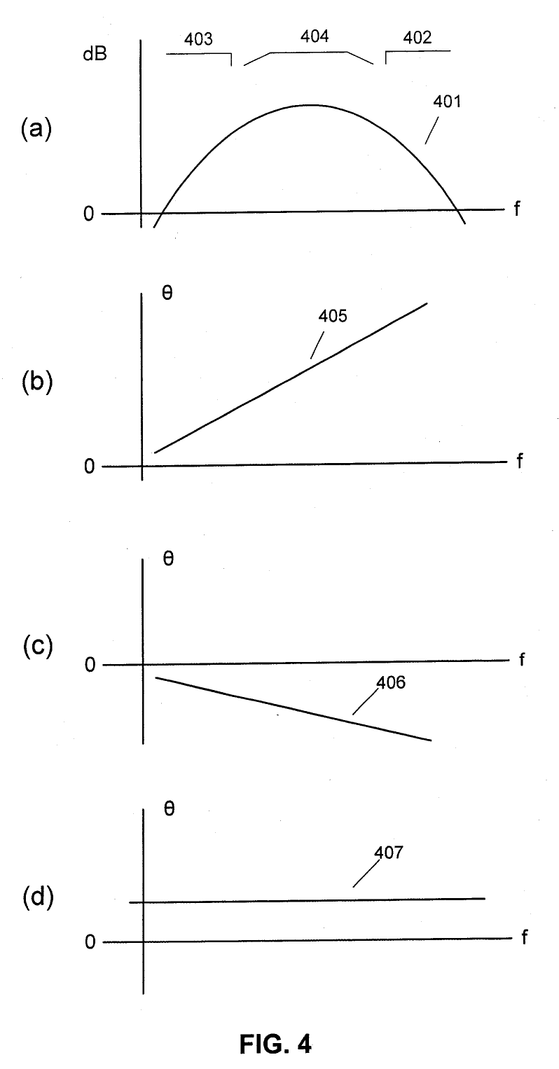

FIG. 4 shows a series of response curves in systems and/or components according to an embodiment of the invention. FIG. 4(a) shows a magnitude response 401 of a speaker, according to an embodiment, such as a response of speaker 305. As shown, the speaker has less response in the lower 403 and higher 402 frequency ranges. For example, a speaker may have the following ranges of responses. A small diameter speaker has in one embodiment a frequency response range from 200 to 5000 Hz, while a large diameter speaker may be one from a range from 100 to 1000 Hz in another embodiment.

FIG. 4(b) shows a phase response 405 of an audio system with phase correction disabled, according to an embodiment of the invention. As shown, there is higher accumulation of phase at higher frequencies. For example, in an uncorrected system, phase may be in the range of 0 degrees at the lowest frequency and in the range of 360 degrees at the highest frequency. FIG. 4(c) shows a possible phase correction 406 provided by a phase correction circuit according to an embodiment. FIG. 4(d) shows a resulting corrected phase 407 of a system with a phase correction circuit according to an embodiment of the invention. In such a system, the output may have a relatively constant phase, according to an embodiment.

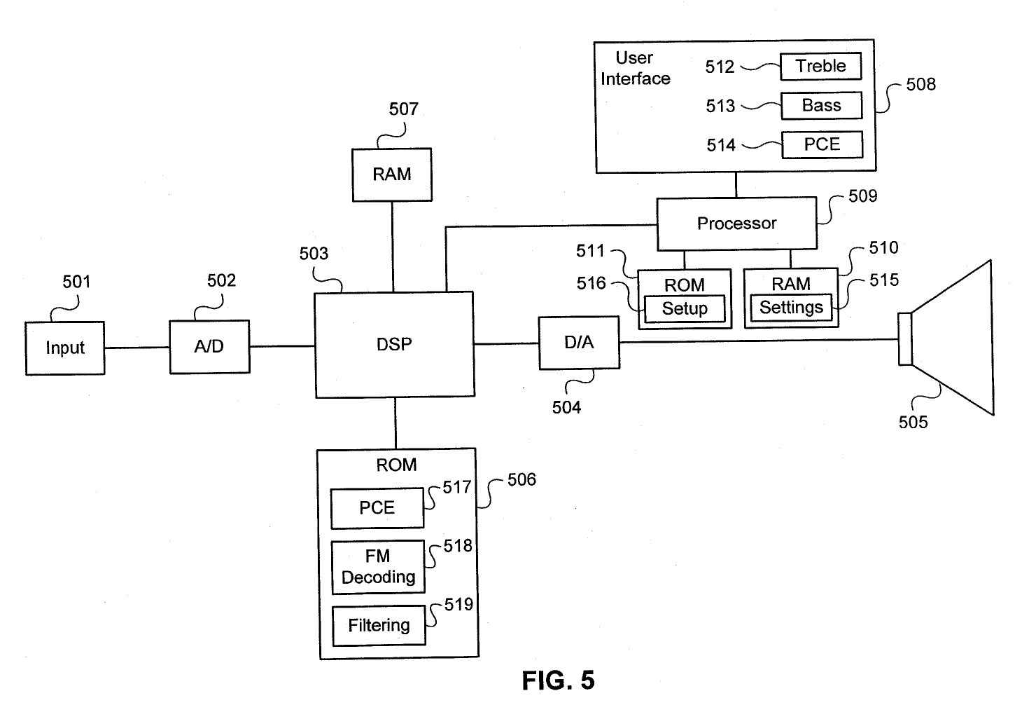

FIG. 5 is a block diagram of a system with a digital signal processor, according to an embodiment of the invention. The system includes input 501, analog to digital converter 502, digital signal processor (DSP) 503, digital to analog converter 504 and speaker 505. Additionally, the system includes RAM 507 and ROM 506. Also included are processor 509, user interface 508, ROM 511 and RAM 510. ROM 506 includes phase corrected equalization code 517, FM decoding code 518 and filtering code 519. ROM 511 includes setup code 516, and RAM 510 includes settings 515. User interface 508 includes treble setup 512, bass setup 513 and phase corrected equalization setup 514.

The system is configured as follows. Analog to digital converter (A/D) 502 is coupled to receive input 501 and provide an output to digital signal processor 503. An output of digital signal processor 503 is coupled to digital to analog converter (D/A) 504, the output of which is coupled to speaker 505. RAM 507 and ROM 506 are each coupled to digital signal processor 503. Additionally, processor 509, which is coupled with ROM 511, RAM 510 and user interface 508, is coupled with digital signal processor 503.

The system shown in FIG. 5 may operate as follows, according to an embodiment. Digital signal processor 503 runs various computer programs stored in ROM 516, such as phase corrected equalization code 517, FM decoding code 518 and filtering code 519. Additional programs may be stored in ROM 506 to enable digital signal processor 503 to perform other digital signal processing and other functions. Digital signal processor 503 uses RAM 507 for storage of items such as settings, parameters, as well as samples upon which digital signal processor 503 is operating.

Digital signal processor 503 receives inputs, which may correspond to audio signals in digital form from a source such as analog to digital converter 502. In another embodiment, audio signals are received by the system directly in digital form, such as in a computer system in which audio signals are received in digital form. Digital signal processor 503 performs various functions such as the processing enabled by programs phase corrected equalization code 517, FM decoding code 518 and filtering code 519. Phase corrected equalization code 517 implements an equalization filter with a correction to increase phase at lower frequencies, according to an embodiment. Such code may implement a filter derived from one in which the inverse of the input is added to the output, as described earlier.

The parameters of the phase corrected equalization code 517 may be stored in ROM 506. However, in an embodiment, parameters such as the null of the filter and the bandwidth may be adjusted during operation of the system. In such instances, the adjustable parameters may be stored in a dynamically writable memory, such as in RAM 507, according to an embodiment. Additionally, bass or treble boosts of a filter implemented in phase correct equalization code 517 may be independently varied over a range of values. Additionally, the width and shape of the filter slopes may be varied over a range of values. Such adjustment may take place over an interface such as user interface 508, and the corresponding parameters are then stored in the system, such as in RAM 507. Output of digital signal processor 503 is provided to digital to analog converter 504. The output of digital to analog converter 504 is in turn provided to speaker 505.

User interface 508 allows for a user to adjust various aspects of the system shown in FIG. 5. For example, a user is able to adjust treble, bass and phase corrected equalization through respective adjustments: treble adjustment 512, bass adjustment 513 and phase corrected equalization adjustment 514. According to an embodiment, phase corrected equalization adjustment 514 comprises a simple enablement or disablement of a phase corrected equalization feature without the ability to adjust respective parameters of the equalizer. According to another embodiment, other adjustments, such as those discussed previously, may be provided over user interface 508 with respect to phase corrected equalization. Processor 509 controls user interface 508 allowing a user to input values and make selections for items such as phase corrected equalization input 514. Such selections and adjustments by the user may be made by way of a user controlled pointing device in a computer system, or through other communication, such as a remote control with infrared communication in the case of a television system. Other forms of user input to the system are possible, according to other embodiments. ROM 511, which is coupled to processor 509, stores programs which allow for control of user interface 508, such as setup program 516. RAM 510, in turn, is used by processor 509 to store the settings selected by a user, as shown here in settings 515.

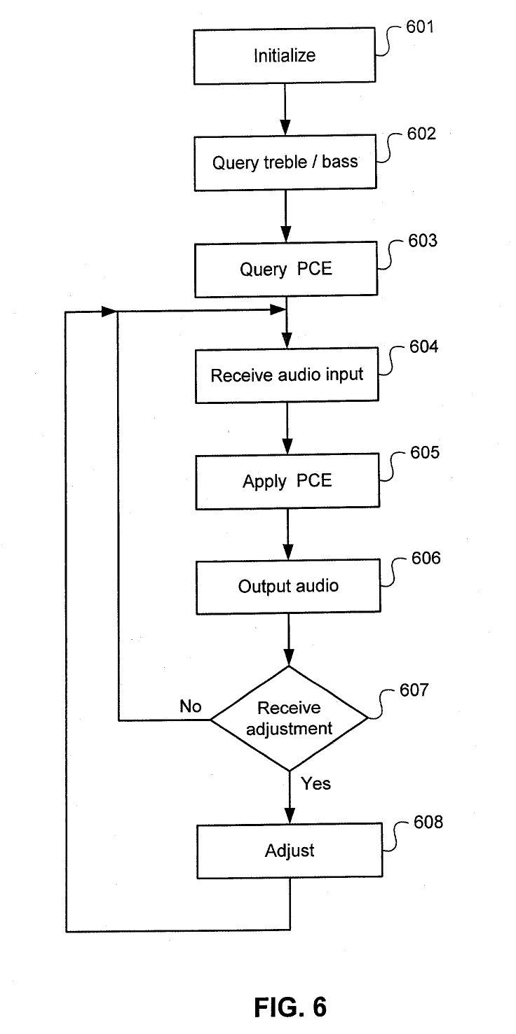

FIG. 6 is a flow diagram of application of equalization, according an embodiment of the invention. First initialize the system (block 601). Initialization may involve setting up of the audio and video in an audio video system. Settings for items such as treble, bass and phase corrected equalization may be initialized at default values, or according to a previous user selection. Treble, bass and other values are queried (block 601). Another query is made for a phase corrected equalization feature (block 603). Such query may be made after query regarding treble, bass and other queries. Alternatively, the query for phase corrected equalization may be made in other order, such as before the query regarding treble, bass and other values. The phase corrected equalization query may include a query regarding enablement or disablement of a respective feature for a phase corrected equalization, or alternatively, may also include a query for particular values for the phase corrected equalization.

A series of audio inputs may be received and processed. As shown, an audio input is received (block 604). Phase corrected equalization is applied to the audio input (block 605). Such phase corrected equalization may occur, according to an embodiment, where a filter is derived from an equalizer in which an input to the equalizer is subtracted to an output of the equalizer, as described previously. The resulting processed audio signal is output (block 606). If no adjustment is received (block 607), then continue to receive audio inputs (block 604). If an adjustment is received (block 607), then make the respective adjustment (block 608), and then continue to receive audio inputs (block 604). As an alternative to where a filter is derived from an equalizer in which an input to the equalizer is subtracted to an output of the equalizer, a filter is derived from one in which there is a summation of the input to the filter and the inverse of the output of the filter, as discussed above.

The process shown in FIG. 6 may be implemented in computer readable code, such as that stored in a computer system with audio capabilities. Such code may also be implemented in an audio video system, such as a television. Further, such process may be implemented in a specialized circuit, such as a specialized digital integrated circuit.

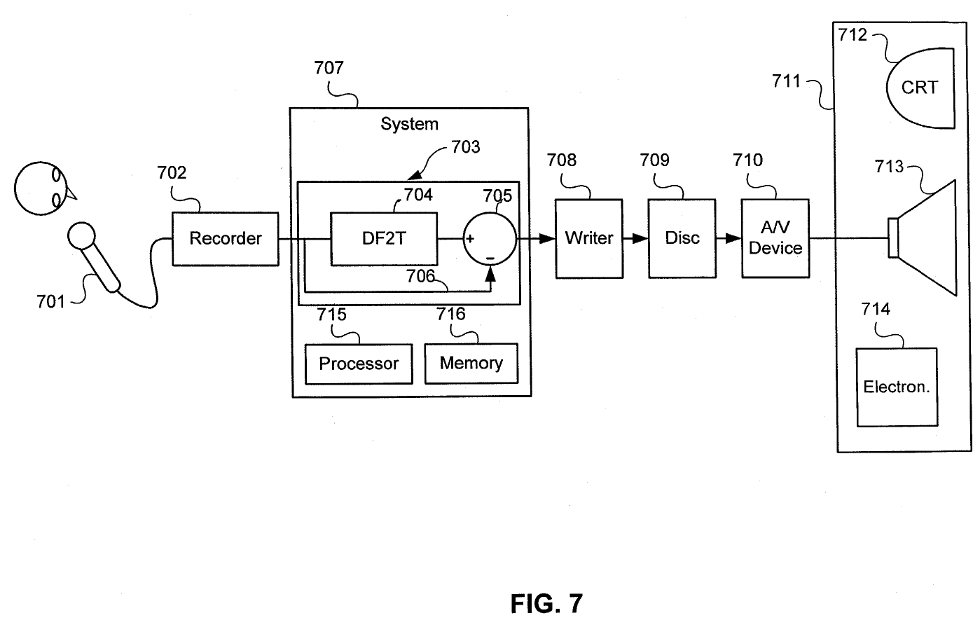

FIG. 7 is a block diagram illustrating production of media according to an embodiment of the invention. The system includes an audio input device 701, recorder 702, computer system 707, media writing device 708 and media 709. Also included is an audio video device 710 coupled with an audio video system 711. Audio video device they comprise of items such as a video recorder, DVD player or other audio video device, audio video device 710 may be replaced with an audio device such as a compact disk or tape player. Audio video system 711 may comprise an item such as a television, monitor, or other electronic system for playing media. Computer system 707 includes phase corrected equalizer logic 703, processor 715 and memory 716. Computer system 707 may include a monitor, keyboard, mouse and other input and output devices. Further, computer system may also comprise a computer-based controller of large volume or other form of a media production and processing system, according to an embodiment. Audio video system 711 includes electronics 714, cathode ray tube 712 and speaker 713.

The system of FIG. 7 may be configured as follows, according to an embodiment. Input device 701 is coupled with recorder 702, the output of which is provided to system 707. The output of system 707 is provided to media writer 708, which is operative upon media 709. Media 709 is provided to audio video device 710, which is coupled with audio video system 711. Phase corrected equalization code 703 includes a biquadradic adjustable parametric equalization filter 704, the output of which is summed with an inverse of its input by summation 705. Such phase corrected equalization code may be implemented as a derivation of such a configuration of an equalizer 704 having its input subtracted from its output.

In operation, an audio signal is received in the system, is processed, and is eventually provided to speaker 713 of audio video system 711. Recorder 702 receives input from input device 701, and records such input. The input may be converted to digital form before or after recording according to different embodiments. The output of recorder is provided to computer system 707. Note that according to an embodiment, input from an input device, such as input device 701, is provided directly to computer system 707 without a separate recorder. The audio signal is processed by phase corrected equalization code 703. Such phase corrected equalization code 703 is run by a processor 715 and stored in a memory 716, according to an embodiment. A phase corrected output is provided to media writer 708, which stores a resulting phase corrected signal on storage medium 709. Such storage medium 709 may comprise a compact disk, DVD, flash memory, tape or other storage medium. The storage medium is then used in audio video device cable of reading storage medium such as storage audio video device 710. Such device reads media and provides an audio output to audio video system 711. Such output may comprise a digital signal, according to one embodiment. In such a case, a digital to analog converter is provided between audio video device 710 and speaker 713. In another embodiment, audio video device 710 provides an analog signal to speaker 713. Speaker 713 produces sound in response to the audio signal from audio video device 710. Additionally, CRT 712 may produce video output in response to a video signal. Such video signal may result from video images stored on medium 709, according to an embodiment.

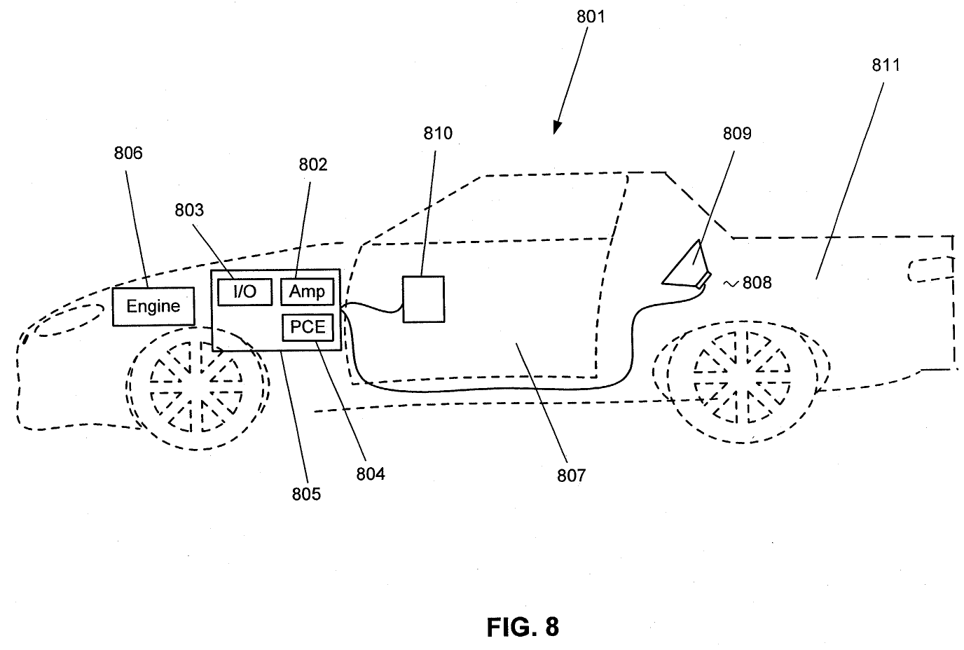

FIG. 8 is an illustrative diagram of a vehicle with stereo system and equalizing filter, according an embodiment of the invention. FIG. 8 shows an automobile 801 which has a stereo system 805. Automobile 801 also includes other elements typically found in an automobile such as engine 806, trunk 811 and door 807. Stereo system 805 includes an amplifier 802, input output circuitry 803 and phase corrected equalization circuit 804. An output of stereo 805 is coupled with speaker 810 and speaker 809. Other speakers are present in other parts of automobile 801, according to various embodiments. Phase corrected equalization circuit 804 may be implemented according to various embodiments described in the present application, including digital and analog embodiments. Speaker 809 is located in an open space 808 in a rear portion of automobile 801. Speaker 810 is located in door 807. Such speakers 809 and 810 are located in open cavities of automobile 801. According to various embodiments, such speakers are mounted without diffusion material, and under non-optimal conditions.

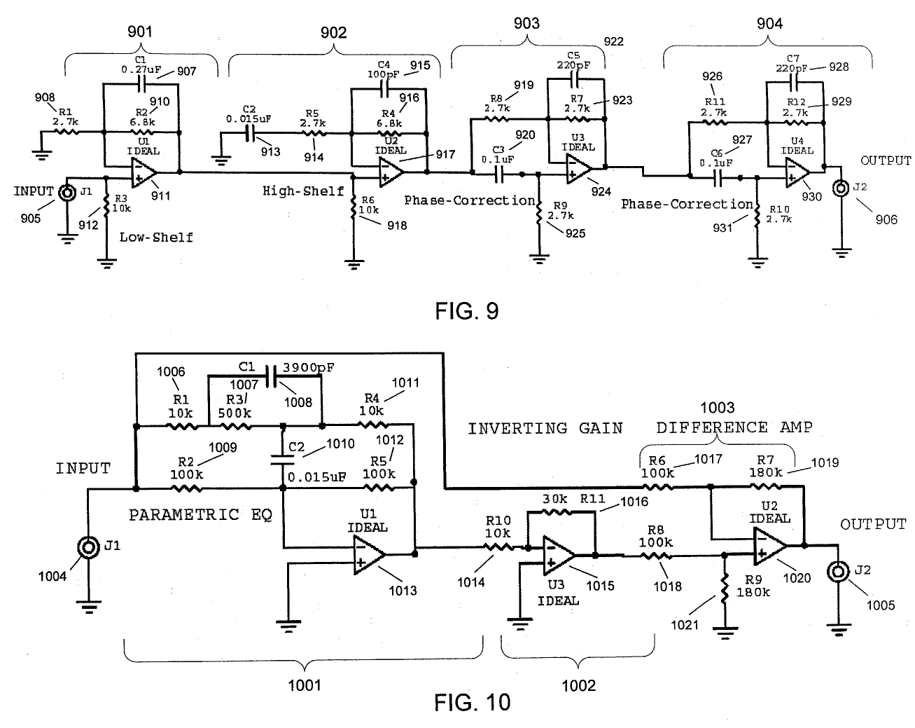

FIG. 9 is a schematic drawing of an analog circuit, according to an embodiment of the invention. The circuit shown includes low-shelf filter 901, high-shelf filter 902, phase correction circuit 903 and phase correction circuit 904. The circuit also includes an input 905 and output 906. As shown, input of low-shelf filter 901 is coupled to input 905, and the output of low-shelf filter 901 is coupled to the input of high-shelf filter 902. The output of high-shelf filter 902 is coupled to the input of phase correction circuit 903, and the output of phase correction circuit 903 is coupled to the input of phase correction circuit 904. Output 906 is coupled to the output of phase correction circuit 904.

The following is a description of construction of the circuit of FIG. 9. Low-shelf filter 901 includes amplifier 911 having its positive terminal coupled to input 905. The output of amplifier 911 is coupled to its negative terminal through capacitor 907 and resistor 910, which are connected in parallel. The negative terminal of amplifier 911 is also connected to ground through resistor 908. High-shelf filter 902 includes amplifier 917 with an input coupled to the output of low-shelf filter 901 and having its output coupled to its negative terminal through capacitor 915 and resistor 916, which are connected in parallel. High-shelf filter 902 also has its negative terminal coupled to ground through resistor 914 and capacitor 913. Phase correction circuit 903 includes amplifier 914, which is coupled to ground through resistor 925 and coupled to the output of high-shelf filter 902 through capacitor 920. The output of amplifier 924 is coupled to its negative terminal through capacitor 922 and resistor 923, which are connected in parallel. The other negative terminal of amplifier 924 is coupled to the input of phase correction circuit 903 through resistor 919. Phase correction circuit 904 includes amplifier 930, which has its positive terminal coupled to ground through resistor 931 and to the output of phase correction circuit 903 through capacitor 927. The output of amplifier 930 is coupled to its negative terminal through capacitor 928 and resistor 929, which are connected in parallel. The negative terminal of amplifier 930 is coupled to the input to phase correction circuit 904 through resistor 926.

The circuit shown in FIG. 9 processes signals as follows. An audio signal is received at input 905. The signal is filtered by low-shelf filter 901 and high-shelf filter 902. Phase correction is provided to the result of the filters by phase correction circuits 903 and 904. A resulting output is provided at output 906. The circuit shown may be implemented in an analog audio system. The circuit may be comprised of separate discrete components, for example on a circuit board. The components may also be implemented on a single integrated circuit. The integrated circuit may be directed to the phase corrected equalization primarily with the components shown. Alternatively, the integrated circuit may have other circuitry related to other audio and other functions for the respective system in which the circuit is used.

More generally, the system includes a set of filters and phase correction circuits. These items may be arranged in different orders. The phase correction circuits 903 and 904 each provide 180° of phase. In other embodiments of the invention, the filters and phase correction circuits shown in FIG. 9 may be varied as follows. The low and high frequency gains can be independently varied, within a range of approximately 0 dB to 20 dB. The low frequency gain (901) is adjusted by way of R2 (910). The high frequency gain is adjusted by way of R4 (916). Each phase correction section (903, 904) provides 180 degrees of phase slope, for a total of 360 degrees across the frequency range. Other arrangements of the respective filters and phase correction circuits may be provided, such as varying their respective order, provided that the system is linear and time invariant. Note that in alternative embodiments of the circuits shown in FIGS. 9, 10 and 11, rather than subtracting the input from the output of the equalizer, the output of the circuit may be derived from subtracting the output of the equalizer from the input to the circuit.

FIG. 10 is a schematic diagram of an analog phase corrected equalization circuit with feed-forward, according to an embodiment of invention. The circuit includes an input 1004, a parametric equalizer circuit 1001, inverting gain circuit 1002, difference amplifier circuit 1003 and output 1005. Input 1004 is coupled to an input of parametric equalizer 1001, and output of parametric equalizer 1001 is coupled to an input to inverting gain circuit 1002. An output inverting gain circuit 1002 is coupled to difference amplifier 1003, and an output of difference amplifier 1003 is coupled to output 1005. Additionally, input 1004 is coupled to another input of difference amplifier 1003.

Parametric equalizer circuit 1001 includes amplifier 1013, which has a positive terminal coupled to ground and a negative terminal coupled to input 1004 through resistor 1009. The output of amplifier 1013 is coupled to its negative terminal through resistor 1012, in parallel with a series combination of resistor 1011 and capacitor 1010. The output of amplifier 1013 is also coupled to input 1004 through a series combination of resistor 1011, resistor 1007 and resistor 1006. A capacitor 1008 as coupled in parallel with resistor 1006 and 1007. Inverting gain circuit 1002 includes an amplifier 1015 having a positive terminal coupled ground and its output coupled to its negative terminal through resistor 1016. A resistor 1014 is coupled between the negative terminal of amplifier 1015 and the output of parametric equalizer 1001. Difference amplifier 1003 has amplifier 1020 with its positive terminal coupled to ground through resistor 1021 and coupled to the output of inverting gain through resistor 1018. An output of amplifier 1020 is coupled to its negative terminal through resistor 1019. The input signal 1004 is coupled to the negative terminal of amplifier 1020 through resistor 1017.

A signal may be processed by the circuit of FIG. 10 as follows. An audio signal is received at input 1004. The audio signal is processed by parametric equalizer 1001, and is also provided to one of the inputs of difference amplifier 1003. A signal resulting from the output of parametric equalizer 1001 is provided to inverting gain circuit 1002. An output signal from inverting gain circuit 1002 is provided to the other input of difference amplifier 1003, that is the input of difference amplifier 1003 other than the one to which input 1004 is provided. Elements of the circuit shown in FIG. 10 may be varied as follows. The independent low and high shelf filters (901 and 902) are combined into a single parametric equalizer (1001) with a gain. The null point (f₀) and depth of the null (Δf) are controlled by way of C1 and C2 (1008 and 1010). The parametric equalizer has a maximum gain of OdB. The inverting gain section (1002) provides 180 degrees of phase shift along with a gain of approximately 9.5 dB. The input signal is then subtracted from the output of the inverting gain section by way of the difference amp (1003). The difference amp has a gain of approximately 5.1 dB.

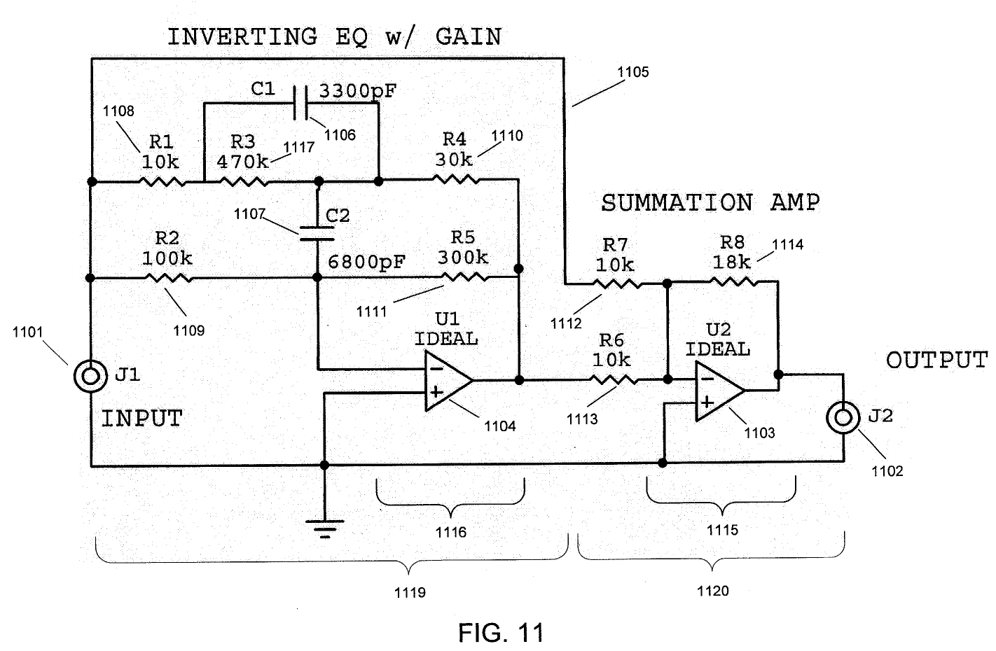

FIG. 11 shows an analog circuit, according to an embodiment of the invention. Included are input 1101, inverting equalizer with gain 1119 and summation amplifier 1120. Inverting equalizier with gain 1119 includes inverting gain 1116 and difference amplifier 1115, inverting gain 1116 and difference amplifier 1115. Inverting gain 1116 includes amplifier 1104, and difference amplifier 1115 includes amplifier 1103. More specifically, inverting equalizer with gain 1119 includes amplifier 1104, resistor 1111, capacitor 1107, resistor 1109, resistor 1108, resistor 1117, resistor 1110 and capacitor 1106. Summation amplifier 1120 includes amplifer 1103, resistor 1113, resistor 1112 and resistor 1114. The positive terminals of amplifier 1104 and 1113 are coupled to ground. Amplifier 1104 has its negative terminal coupled to input 1101 through resistor 1109. An output of amplifier 1104 is coupled to its input through resistor 1111. The output of amplifier 1104 is also coupled to input 1101 through resistor 1110, resistor 1117, resistor 1108 and resistor 1009. Capacitor 1106 is coupled and parallel with resistor 1117. FIG. 111 shows an embodiment with the single parametric equalizer combined with the inverting gain section (1119). This combination has a gain of approximately 10 dB. The null point (f₀) and depth of the null (Δf) are controlled via C1 and C2 (1106, 1107). The input signal is then combined with the original input signal in a summation/gain section with approximately 5.1 dB of gain (1120).

In general, the output of inverting equalizer with gain 1119 is provided to summation amplifier 1120. The input 1101 is also provided by way of connection 1105 to summation amplifier 1120.

The foregoing description of various embodiments of the invention has been presented for purposes of illustration and description. It is not intended to limit the invention to the precise forms described.

What is claimed is:

1. A load correction system comprising:
an audio source signal;
a parametric equalizer coupled to receive the source signal;
a summation configured provide a difference between the source signal and an output of the equalizer;
an amplifier configured to receive an output of the summation; and
a speaker coupled to receive an output of the amplifier.

2. The system of claim 1, wherein the equalizer comprises an adjustable equalizer.

3. The system of claim 1, including a digital signal processor implementing the equalizer and summation.

4. The system of claim 1, wherein, in absence of the filter, a combination of the speaker and electronic components coupled with the speaker have a larger amount of phase at low frequencies and a smaller amount of phase at high frequencies.

5. The system of claim 1, wherein the summation adds an inverse of the source signal to an output of the equalizer.

6. The system of claim 1, wherein the summation adds the source signal to an inverse of an output of the equalizer.

7. An audio system comprising:
an enclosure comprising a synthetic material;
one or more speakers coupled to an interior surface of the enclosure;
electronic components and a display device, the electronic components and the display device being contained in the enclosure and the electronic components including an amplifier coupled to at least one of the one or more speakers; and
an integrated circuit having
an input circuit configured to receive a source signal,
a filter having coefficients, the coefficients derived from a parametric equalizer coupled to a summation of a difference between an input to the equalizer and an output of the equalizer, and
an output circuit configured to receive and output an output of the filter, the output circuit being coupled to an input of the amplifier.

8. The system of claim 7, wherein the synthetic material comprises plastic.

9. The system of claim 7, wherein at least one of the one or more speakers and the display device are located in a single cavity in the enclosure.

10. The system of claim 7, wherein the display device comprises a cathode ray tube.

11. The system of claim 7, wherein the display device comprises a flat panel display.

12. The system of claim 7, wherein the speakers have a single cone.

13. The system of claim 7, wherein all speakers in the system are of the same size.

14. The system of claim 7, including a user interface that provides for disabling the filter and adjustment of treble and bass.

15. The system of claim 7, wherein, in absence of the filter, a combination of the electronic components and the speaker have a larger amount of phase at low frequencies and a smaller amount of phase at low frequencies.

16. The system of claim 7, wherein the summation combines an inverse of an input to the equalizer and an output of the equalizer.

17. An audio system comprising:
one or more speakers;
an amplifier;
electronic components; and
an integrated circuit having
an input circuit configured to receive a source signal,
a filter having coefficients, the coefficients derived from a parametric equalizer coupled to a summation of a difference between an input to the equalizer and an output of the equalizer, and
an output circuit to receive and output an output of the filter, the output circuit being coupled to an input of the amplifier.

18. The system of claim 17, including a magnetic tape audio and video reading device, the source signal being supplied by the reading device.

19. The system of claim 17, including a portable headphone that comprises the speaker.

20. The system of claim 17, including digital versatile disk (DVD) reading logic, the DVD reading logic supplying the source signal.

21. The system of claim 17, including super audio CD (SACD) reading logic, the SACD reading logic supplying the source signal.

22. The system of claim 17, including a processor, hard drive storage device, display device and telecommunications software.

23. The system of claim 17, the speaker being housed in a cavity of an automobile.

24. The system of claim 23, the cavity comprising a cavity in a door of the automobile.

25. The system of claim 17, wherein, in absence of the filter, a combination of the electronic components and the speaker have a larger amount of phase at low frequencies and a smaller amount of phase at high frequencies.

26. The system of claim 17, including stereo electronics and a second speaker.

27. A method of signal processing comprising:
deriving a filter from a parametric equalizer coupled to a summation of a difference between an input to the equalizer and an output of the equalizer;
receiving a source signal;
applying the filter to the source signal;
providing an output of the filter to-an amplifier coupled to a speaker.

28. The method of claim 27, wherein summation combines an inverse of the source signal with an output of the equalizer

29. The method of claim 27, wherein the summation combines the source signal with an inverse of an output of the equalizer.

30. A load correction circuit comprising:
an input circuit configured to receive a source signal;
a filter having coefficients, the coefficients derived from a parametric equalizer coupled to a summation of a difference between an input to the equalizer and an output of the equalizer; and
a circuit to receive and output an output of the filter to an amplifier.

31. The circuit of claim 30, wherein the equalizer comprises an adjustable parametric equalizer.

32. The circuit of claim 30, including a digital signal processor and a memory to store computer readable instructions implementing the filter.

33. The circuit of claim 30, the coefficients being adjustable after at least some use of the circuit.

34. The circuit of claim 30 including circuitry to disable the filter in response to a user input.

35. The system of claim 30, wherein the summation combines an inverse of an input to the equalizer and an output of the equalizer.
